(19) United States
(12) Patent Application Publication
(10) Pub. No.: US 2026/0058618 A1
(43) Pub. Date: Feb. 26, 2026

(54) CONFIGURABLE RADIO FREQUENCY AMPLIFIER

(71) Applicant: Realtek Semiconductor Corp., Hsinchu (TW)

(72) Inventor: Chia-Liang (Leon) Lin, Fremont, CA (US)

(21) Appl. No.: 18/812,065

(22) Filed: Aug. 22, 2024

(51) Int. Cl. H03F 3/24

(52) U.S. Cl. CPC H03F 3/245; H03F 2200/451

(57) ABSTRACT

A radio frequency power amplifier (RFA) including: an n-type common-source amplifier (NCSA) used to convert a first voltage signal into a first current signal; an n-type common-gate amplifier (NCGA) relaying the first current signal into a second current signal directed to an output node based on a first bias voltage; a p-type common-source amplifier (PCSA) powered by a first power supply to convert a second voltage signal into a third current signal; a p-type common-gate amplifier (PCGA) relaying the third current signal into a fourth current signal directed to the output node based on a second bias voltage; and an inductor attached to the output node and featuring a center tap, wherein while in a low-power mode, the second bias voltage is set to a level that turns off the PCGA, and the central node has a low impedance and a DC voltage determined by a second power supply.

### BACKGROUND OF THE INVENTION

### Field of the Invention

The present invention pertains to radio frequency amplifiers, and more specifically to radio frequency amplifiers that are configurable.

### Description of Related Art

As is known, an amplifier takes an input voltage at a certain frequency and produces an amplified output voltage that is passed on to a load. A radio frequency amplifier (RFA) specifically amplifies voltages in the radio frequency range, which include frequencies from several tens of mega-Hertz to several tens of giga-Hertz.

A metal-oxide-semiconductor transistor (MOST) is a type of active component that includes a source, gate, and drain, commonly utilized for constructing amplifiers. This device can be categorized into NMOST (n-channel MOST) or PMOST (p-channel MOST) transistors. It operates with a particular threshold voltage. When the gate-to-source voltage exceeds this threshold, while the gate-to-drain voltage remains below it, the MOST is in a “saturation region” where it effectively functions as an amplifier to output a drain current in response to the gate-to-source voltage. Conversely, when both the gate-to-source and gate-to-drain voltages surpass the threshold, the MOST is in a “triode region,” where it acts effectively as a switch. When the gate-to-source voltage is below the threshold voltage, the MOST is turned off and the drain current is zero.

A metal-oxide-semiconductor transistor (MOST) can be arranged as a common-source amplifier that converts input voltage from its gate into output current from its drain. The source is tied to a low-impedance point, ensuring the source voltage stays relatively static despite variations in input voltage. An incremental variation in input voltage leads to a corresponding variation in output current. The measure of this responsiveness is termed “transconductance,” describing the conversion efficiency from input voltage to output current. Transconductance decreases with “source degeneration,” which occurs when the source impedance is not sufficiently low. Assessing the linearity of a common-source amplifier involves examining how transconductance remains consistent amid increasing voltage swings. To achieve optimal linearity, it is crucial for the MOST to operate in its “saturation region” throughout the largest possible range of input voltage swings.

Alternatively, a MOST can function as a common-gate amplifier, processing input current at its source and delivering output current at its drain. The gate is connected to a low-impedance node to stabilize gate voltage, regardless of fluctuations in input current. This configuration efficiently channels input current into output current, allowing for essentially equal incremental changes between the two currents.

Moreover, a second MOST can be tandemly aligned with a first one in a “cascode” configuration, wherein both devices share a common current pathway, and the output current of the first serves as the input current to the second. One advantage of a cascode arrangement is good reverse isolation; that is, changes in the load conditions at the drain of the second MOST have little effects on the performance of the first.

The performance of a radio frequency amplifier is evaluated based on factors such as voltage gain, maximum output power, and efficiency. Voltage gain reflects the increase of level from input to output voltage, whereas efficiency indicates how much energy is effectively utilized versus consumed by the amplifier. Typically, there are compromises to be made between these different factors.

There is a desire for a radio frequency amplifier designed to adjust these tradeoffs to suit diverse application requirements.

### BRIEF SUMMARY OF THIS INVENTION

In an embodiment, a radio frequency power amplifier includes: an n-type common-source amplifier (NCSA) used to convert a first voltage signal into a first current signal; an n-type common-gate amplifier (NCGA) relaying the first current signal into a second current signal directed to an output node based on a first bias voltage; a p-type common-source amplifier (PCSA) powered by a first power supply to convert a second voltage signal into a third current signal; a p-type common-gate amplifier (PCGA) relaying the third current signal into a fourth current signal directed to the output node based on a second bias voltage; and an inductor attached to the output node and featuring a center tap linked to a central node, wherein: the first voltage signal and the second voltage signal have the same frequency and phase and approximately the same amplitude, and in a high-power mode, the central node has a high impedance, while in a low-power mode, the second bias voltage is set to a level that turns off the PCGA, and the central node has a low impedance and a DC voltage determined by a second power supply.

### BRIEF DESCRIPTION OF THE DRAWINGS

FIG. 1 presents a schematic of a configurable RF amplifier as described in this disclosure.

FIG. 2 illustrates a schematic of a trifilar transformer suitable for use with the RF amplifier from FIG. 1.

FIG. 3 depicts a schematic of a bias network compatible with the RF amplifier shown in FIG. 1.

FIG. 4 shows a current-to-voltage converter that can be used in conjunction with the radio frequency amplifier of FIG. 1.

### DETAILED DESCRIPTION OF THIS INVENTION

The present invention relates to amplifiers. While the specification describes several example embodiments of the invention considered favorable modes of practicing the invention, it should be understood that the invention can be implemented in many ways and is not limited to the particular examples described below or to the particular manner in which any features of such examples are implemented. In other instances, well-known details are not shown or described to avoid obscuring aspects of the invention.

Persons of ordinary skill in the art understand terms and basic concepts related to microelectronics that are used in this disclosure, such as “voltage,” “current,” “signal,” “frequency,” “differential signal,” “capacitor,” “inductor,” “resistor,” “transistor,” “MOST (metal-oxide semiconductor field-effect transistor),” “PMOST (p-channel metal oxide semiconductor field-effect transistor),” “NMOST (n-channel metal oxide semiconductor field-effect transistor),” “AC (alternating current),” “DC (direct current),” “source,” “gate,” “drain,” “node,” “ground node,” “power supply node,” “cascode,” “amplifier,” “common-source,” “common-gate,” “transconductance,” “admittance,” and “impedance.” For brevity, in this present disclosure, “field effect transistor” is simply referred to as “transistor.” Individuals with ordinary skill in the field can identify symbols for an inductor, capacitor, switch, inverter, NMOS transistor, and PMOS transistor, and can identify “source,” “gate,” and “drain” of MOS transistor, for both NMOS and PMOS. Terms and basic concepts like these are apparent to those of ordinary skill in the art and thus will not be explained in detail here. Those of ordinary skill in the field are able to interpret schematics and understand the interconnections between circuit elements with no need for elaborate explanations.

A signal is a voltage or current of a variable level that carries certain information and can vary with time. The level of the signal at a moment represents the state of the signal at that moment.

In this document, the abbreviation “DC” refers to direct current, while “AC” denotes alternating current. Any signal may be broken down into a DC part, which is essentially constant, and an AC part, which is largely characterized by its fluctuation.

A DC node is a node of a substantially fixed electric potential. In particular, “V_{DD}” denotes a first special DC node referred to as a power node, and “V_{SS}” denotes a second special DC node referred to as a ground node. In this present disclosure, “V_{DD} is 1.2V” means “the voltage level of the power supply node V_{DD} is 1.2V”; this will be clear in the context without causing confusion.

A logical signal has two states: low (0) and high (1). When “Q is high” or “Q is low” is stated, it means Q is in its respective 1 or 0 state.

A MOST (either NMOST or PMOST) is said to be in a “diode-connect” configuration or topology when its gate is shorted to its drain.

An inverter takes a logical input signal and produces an output signal that is the inverse of the input. That is, when the input signal is 1 (0), the output signal will be 0 (1).

A switch operates based on a logical signal, acting as a short circuit when the signal is 1 and an open circuit when it's 0.

Throughout this disclosure, differential (signal) embodiment is widely used, wherein a signal comprises a first voltage and a second voltage denoted with suffixes “+” and “−,” respectively, attached in subscript, and the first voltage and the second voltage have the same DC component but opposite AC component. For instance, a signal V₁ in a differential embodiment comprises two voltages V₁₊ and V₁₋, wherein V₁₊ and V₁₋ have the same DC component but opposite AC components. Likewise, in differential embodiment, an output node ON comprises two nodes ON₊ and ON₋.

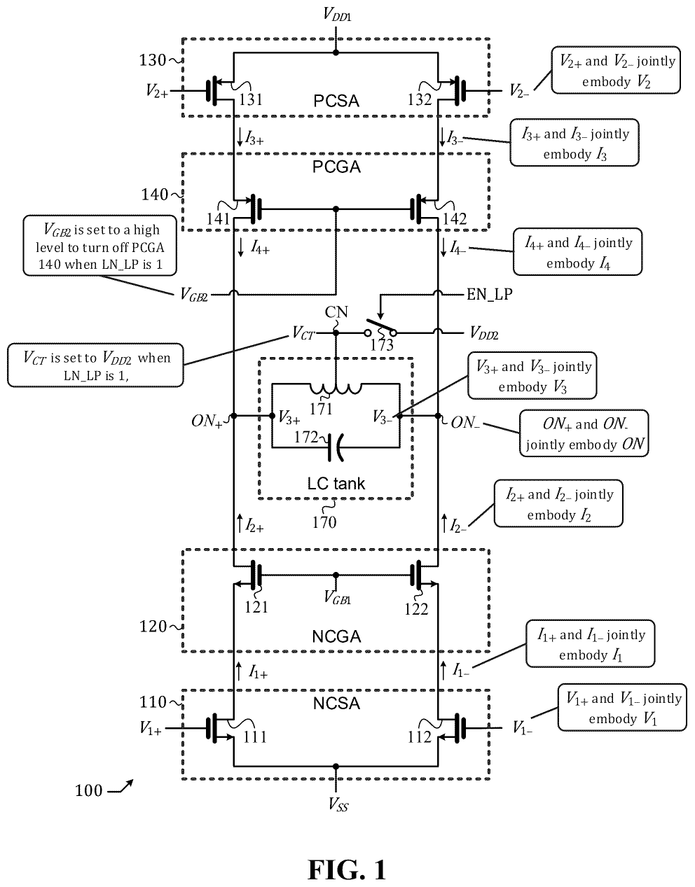

A schematic diagram of a radio frequency amplifier (RFA) 100 in accordance with an embodiment of the present disclosure is shown in FIG. 1. RFA 100 includes an n-type common-source amplifier (NCSA) 110 established upon a ground node “V_{SS}” and configured to convert a first voltage signal V₁ (jointly embodied by two voltages V₁₊ and V₁₋ in differential embodiment) into a first current signal I₁ (jointly embodied by two currents I₊ and I in a differential embodiment); an n-type common-gate amplifier (NCGA) 120 controlled by a first gate bias voltage V_{GB1} and configured to relay the first current signal I₁ into a second current signal I₂ (jointly embodied by two currents I₂₊ and I₂₋ in a differential embodiment) directed to an output node ON (jointly embodied by two nodes ON₊ and ON₋ in a differential embodiment); a p-type common-source amplifier (PCSA) 130 powered by a first power supply “V_{DD1}” and configured to convert a second voltage signal V₂ (jointly embodied by two voltages V₂₊ and V₂₋ in a differential embodiment) into a third current signal I₃ (jointly embodied by two currents I₃₊ and I₃₋ in a differential embodiment); a p-type common-gate amplifier (PCGA) 140 controlled by a second gate bias volage V_{GB2} and configured to relay the third current signal I₃ into a fourth current signal I₄ (jointly embodied by two currents I₄₊ and I₄₋ in a differential embodiment) directed to the output node ON (jointly embodied by two nodes ON₊ and ON₋ in a differential embodiment); and a LC tank 170 comprising a parallel connection of a capacitor 172 and an inductor 171 with a center tap attached to a central node CN of voltage V_{CT} that directly couples to a second power supply “V_{DD2}” through a switch 173 controlled by a logical signal EN_LP. When EN_LP is 1, switch 173 is turned on and CN is effectively shorted to “V_{DD2}”; otherwise, CN is of a high impedance and disconnected from “V_{DD2}.” When EN_LP is 0, V_{GB2} is set to a proper level that can effectively enable the amplifier function of PCGA 140; otherwise, V_{GB2} is set to a sufficiently high level that can effectively turns off PCGA 140.

RFA 100 is configurable and can operate in either a low-power mode by setting EN_LP to 1 or a high-power mode by setting EN_LP to 0. When EN_LP is 0, NCSA 110 and NCGA 120 jointly convert V₁ to I₂, PCSA 130 and PCGA 140 jointly convert V₂ to I₄, while I₂ and I₄ are summed at the output node ON to establish an output voltage signal V₃ (jointly embodied by two voltages V₃₊ and V₃₋ in a differential embodiment) across the LC tank 170. In this case, the central node CN has a high impedance, and V_{CT} is determined by a DC level of V₁, V_{GB1}, a DC level of V₂, and V_{GB2}, and is typically half of the voltage level of V_{DD1}. When EN_LP is 1, PCGA 140 is turned off, and I₄ is zero. In this case, V_{CT} is equal to V_{DD2}. To have substantial power saving in the low-power mode, V_{DD2} must be substantially lower than V_{DD1}. In an embodiment, a DC level of V_{DD2} is no higher than half of a DC level of V_{DD1}. This way, the power saving in the low-power mode is at least 50%.

NCSA 110 comprises two NMOS transistors 111 and 112. NCGA 120 comprises two NMOS transistors 121 and 122. PCSA 130 comprises two PMOS transistors 131 and 132. PCGA 140 comprises two PMOS transistors 141 and 142. NMOS transistors 111 (112) and 121 (122) are stacked up in a cascode topology. Likewise, PMOS transistors 131 (132) and 141 (142) are stacked up in a cascode topology. These are all clear to those of ordinary skill in the art and thus not further explained.

Mathematically, in an embodiment, V₁₊, V₁₋, V₂₊, and V₂₋ can be modeled by the following equations:

$${V}_{1 +} = {V}_{BN} + {A}_{N} ( t ) sin ( ω t + {φ}_{N} ( t ) ) \qquad ( 1 )$$

$${V}_{1 -} = {V}_{BN} - {A}_{N} ( t ) sin ( ω t + {φ}_{N} ( t ) ) \qquad ( 2 )$$

$${V}_{2 +} = {V}_{BP} + {A}_{P} ( t ) sin ( ω t + {φ}_{P} ( t ) ) \qquad ( 3 )$$

$${V}_{2 -} = {V}_{BP} + {A}_{P} ( t ) sin ( ω t + {φ}_{P} ( t ) ) \qquad ( 4 )$$

Here, t denotes a time variable; ω denotes an angular frequency of an input signal; V_{BN} denotes a DC (direct current) level of V₁₊ and V₁₋; V_{BP} denotes a DC level of V₂₊ and V₂₋; A_{N}(t) and φ_{N} (t) denote time-varying amplitude and phase, respectively, of the first signal V₁; and A_{P}(t) and φ_{P}(t) denote time-varying amplitude and phase, respectively, of the second signal V₂. In a preferred yet nonbinding embodiment, A_{N}(t) is the same as A_{P}(t), while φ_{N}(t) is the same as φ_{P}(t). V_{BN} determines the DC level of the gates of NMOS transistors 111 and 112, while V_{BP} determines the DC level of the gates of PMOS transistors 131 and 132.

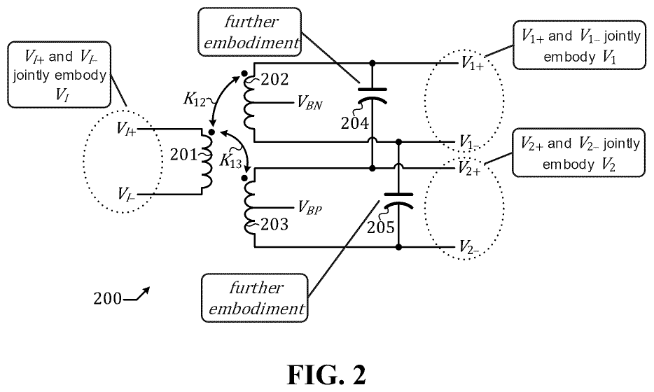

V₁ and V₂ are AC (alternating current) coupled from an input signal V, (jointly embodied by V₁₊ and V₁₋ in differential embodiment) using an AC coupling network. In an embodiment shown in FIG. 2, the AC coupling network includes a trifilar transformer 200 comprising: a primary inductor 201 configured to receive V₁₊ and V₁₋; a first secondary inductor 202 configured to couple V₁₊ and V₁₋ into V₁₊ and V₁₋ via a first magnetic coupling K₁₂ with the primary inductor 201; and a second secondary inductor 203 configured to couple V₁₊ and V₁₋ into V₂₊ and V₂₋ via a second magnetic coupling K₁₃ with the primary inductor 201. The center taps of the first secondary inductor 202 and the second secondary inductor 203 connect to V_{BN} and V_{BP}, respectively. In an embodiment, the first secondary inductor 202 and the second secondary inductor 203 have approximately the same inductance, while K₁₂ and K₁₃ have approximately the same value. In a further embodiment, V₁₊ and V₂₊ are equalized via a first equalizing capacitor 204, while V₁₋ and V₂₋ are equalized via a second equalizing capacitor 205. When capacitors 204 and 205 have sufficiently small impedance, they will force V₁₊ and V₁₋ to be substantially equal to V₂₊ and V₂₋, respectively, hence forcing V₁ to be equal to V₂ (as far as AC components are concerned).

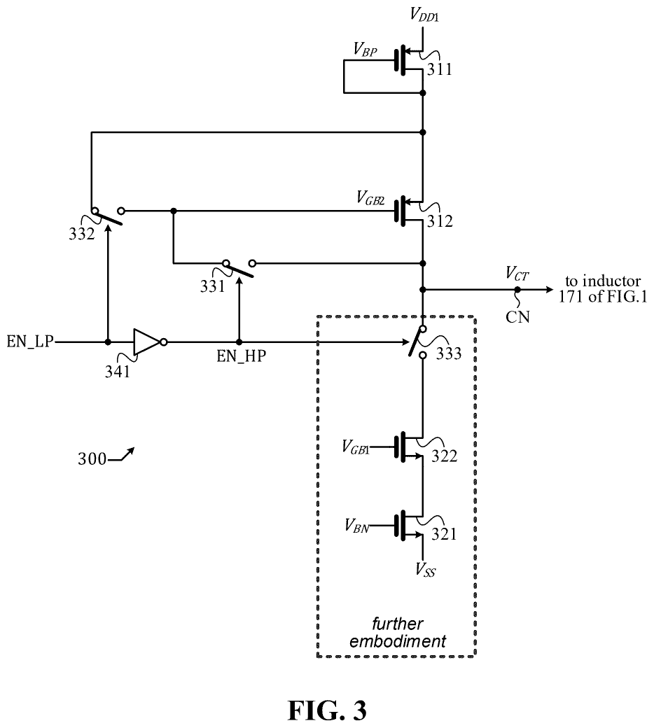

In an embodiment, a bias network 300 shown in FIG. 3 is used to establish V_{BP} and V_{GB2}. The bias network 300 comprises PMOS transistors 311 and 312, the gate voltages of which are utilized to establish V_{BP} and V_{GB2}, respectively. PMOST 311 is configured in a diode-connect topology by shorting its gate to its drain, establishing its gate voltage for V_{BP}. Biasing network 300 further includes two switches 331 and 332 controlled by EN_HP and EN_LP, respectively, wherein EN_HP is a logical inversion of EN_LP and generated by inverter 341. The function of the bias network 300 depends on EN_LP and will be explained as follows.

When EN_LP is 0 and consequently EN_HP is 1, PMOST 312 is effectively set up in a diode-connect configuration by shorting its gate to its drain via switch 331, establishing the gate voltage for V_{GB2}. The drain of PMOST 312 connects to the central node CN of inductor 171, at which the voltage is V_{CT} (please see FIG. 1). When V_{CT} rises (falls), both V_{BP} and V_{GB2} will rise (fall), causing PMOS transistors 131, 132, 141, and 142 to conduct less (more) currents and thus lowering (raising) I₄₊ and I₄₋ and consequently lowering (raising) V₃₊, V₃₋, and also V_{CT}. This way, a negative feedback mechanism is formed and forcing V_{BP}, V_{GB2}, and V_{CT} to settle to stable levels. In a further embodiment, bias network 300 further includes NMOS transistors 321 and 322 configured in a stack-up topology with gate voltages of V_{BN} and V_{GB1}, respectively. The drain of NMOST 322 connects to CN via switch 333 controlled by EN_HP. When EN_HP is 1, NMOS transistors 321 and 322 can draw current from the central node CN and neutralize the impact of PMOS transistors 311 and 312 that inject current into the central node CN.

When EN_LP is 1 and consequently EN_HP is 0, the gate and the source of PMOST 312 are effectively shorted via switch 332, thus shutting off PMOST 312 and the outlet of the drain current of PMOST 311, and consequently also shutting off PMOST 311 by forcing V_{BP} to be no lower than V_{DD1} minus the threshold voltage of PMOST 311. In this case, V_{GB2} is equal to V_{BP} and both are sufficiently high to turn off PMOST 131, 132, 141, and 142 and thus disabling the amplifier function of PCGA 140.

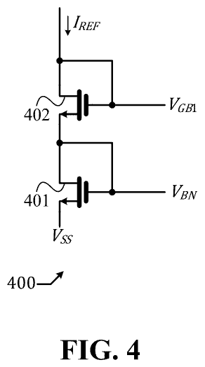

In a further embodiment illustrated by FIG. 4, V_{BN} and V_{GB1} are established using a current-to-voltage converter 400 comprising a stack up of NMOS transistors 401 and 402, both configured in diode-connect topology with gate voltages determining V_{BN} and V_{GB1}, respectively, in response to a reference current I_{REF} injected into the drain of NMOST 402. This way, a likewise stack-up of two NMOS transistors with gate voltages controlled by V_{BN} and V_{GB1}, respectively, such as NMOS transistors 111 (112) and 121 (122), can be biased to have a current proportional to the reference current I_{REF} in accordance with width-to-length ratios of transistors. This concept, which is known as current mirroring, can be well understood by those of ordinary skill in the art and is thus not further explained herein.

By way of example but not limitation: RFA 100 is fabricated using a 28 nm CMOS process technology; V_{DD1} is 3V; V_{DD2} is 1.2V; V_{SS} is 0V; NMOST 111, 112, 121, and 122 have the same threshold voltage 0.4V, the same channel length 30 nm, and the same width 2 mm; PMOST 131, 132, 141, and 142 have the same threshold voltage 0.4V, the same channel length 30 nm, and the same width 2.4 mm; V_{BN} is 0.5V; V_{GB1} is 1.1V; V_{BP} is 2.5V when EN_LP is 0, and 2.2V when EN_LP is 1; V_{GB2} is 1.9V when EN_LP is 0 and 2.2V when EN_LP is 1; ω is 2π times 5 GHz; inductor 171 is 1 nH; and capacitor 172 is 500 fF. This way, NMOST 111, 112, 121, and 122 are all biased in the saturation region regardless of EN_LP; PMOST 131, 132, 141, and 142 are biased in the saturation region when EN_LP is 0 and turned off when EN_LP is 1.

Those skilled in the art can choose to add an additional transistor to the transistor stack-up topology to enhance reverse isolation or to reduce stress on neighboring transistors, besides what is described in the present disclosure.

Those skilled in the art will readily observe that numerous modifications and alterations of the device and method may be made while retaining the teachings of the invention. Accordingly, the above disclosure should be construed as limited only by the metes and bounds of the appended claims, which properly construed from the perspective of an artisan in view of the present disclosure.

What is claimed is:

1. A radio frequency power amplifier (RFA) including:
an n-type common-source amplifier (NCSA) used to convert a first voltage signal into a first current signal;
an n-type common-gate amplifier (NCGA) relaying the first current signal into a second current signal directed to an output node based on a first bias voltage;
a p-type common-source amplifier (PCSA) powered by a first power supply to convert a second voltage signal into a third current signal;
a p-type common-gate amplifier (PCGA) relaying the third current signal into a fourth current signal directed to the output node based on a second bias voltage; and
an inductor attached to the output node and featuring a center tap linked to a central node, wherein: the first voltage signal and the second voltage signal have the same frequency and phase and approximately the same amplitude, and in a high-power mode, the central node has a high impedance, while in a low-power mode, the second bias voltage is set to a level that turns off the PCGA, and the central node has a low impedance and a DC voltage of a second power supply.

2. The RFA of claim 1, wherein the first voltage signal and the second voltage signal are coupled via a capacitor.

3. The RFA of claim 1, wherein the first voltage signal and the second voltage signal are AC (alternating current) coupled from an input voltage signal using an AC coupling network.

4. The RFA of claim 3, wherein the AC coupling network comprises a trifilar transformer including: a primary inductor configured to receive the input voltage signal; a first secondary inductor configured to couple the input voltage signal into the first voltage signal via a first magnetic coupling with the primary inductor; and a second secondary inductor configured to couple the input voltage signal into the second voltage signal via a second magnetic coupling with the primary inductor.

5. The RFA of claim 4, wherein center taps of the first secondary inductor and the second secondary inductor connect to DC (direct current) levels of the first voltage signal and the second voltage signal, respectively.

6. The RFA of claim 1 further including: a bias network comprising a first PMOST (p-channel metal oxide semiconductor transistor) and a second PMOST, configured in a stack-up topology and powered by the first power supply on a source of the first PMOST and connected to the central node on a drain of the second PMOST, wherein a gate voltage of the first PMOST is used to set a DC level of the second voltage signal, and a gate voltage of the second PMOST is used to determine a second bias volage.

7. The RFA of claim 6, wherein in the high-power mode, both the first PMOST and the second PMOST are configured in a diode-connect topology, while in the low-power mode, a gate and a source of the second PMOST are shorted.

8. The RFA of claim 6 further comprising a first NMOST (n-channel metal oxide semiconductor transistor) and a second NMOST, configured in a stack-up topology with a drain of the second NMOST connecting to the central node, wherein a gate voltage of the first NMOST is equal to the DC level of the first voltage signal, and a gate voltage of the second NMOST is equal to the first bias voltage.

9. The RFA of claim 1 further comprising a current-to-voltage converter including a first NMOST (n-channel metal oxide semiconductor transistor) and a second NMOST, configured in a stack-up topology to receive a reference current from a drain of the second NMOST and establish accordingly a DC level of the first voltage signal and the first bias voltage, respectively.

10. The RFA of claim 1, wherein a DC level of the second power supply is not higher than half of a DC level of the first power supply.
